(19) United States
(12) Patent Application Publication
(10) Pub. No.: US 2025/0227915 A1
(43) Pub. Date: Jul. 10, 2025

(54) METHODS AND DEVICES FOR REDUCED FLOATING BODY EFFECT IN ADVANCED DRAM

(71) Applicant: Applied Materials, Inc., Santa Clara, CA (US)

(72) Inventors: Ashish PAL, San Ramon, CA (US); Leitao LIU, Sunnyvale, CA (US); El Mehdi BAZIZI, San Jose, CA (US); Fredrick FISHBURN, Belmont, CA (US); Zhijun CHEN, San Jose, CA (US); Raghuveer S. MAKALA, Campbell, CA (US); Sony VARGHESE, Manchester, MA (US); Tong LIU, Folsom, CA (US); Balasubramanian PRANATHARTHIHARAN, San Jose, CA (US); Lequn LIU, San Jose, CA (US)

(73) Assignee: Applied Materials, Inc., Santa Clara, CA (US)

(21) Appl. No.: 18/972,004

(22) Filed: Dec. 6, 2024

Related U.S. Application Data
(60) Provisional application No. 63/619,180, filed on Jan. 9, 2024.

(51) Int. Cl. H10B 12/00

(52) U.S. Cl. CPC H10B 12/315; H10B 12/05

(57) ABSTRACT

The present technology includes vertical cell dynamic random-access memory (DRAM) arrays with improved floating body effect. The arrays include one or more bit lines arranged in a first horizontal direction and one or more word lines arranged in a second horizontal direction. The arrays include one or more channels extending in a vertical direction generally orthogonal to the first direction and the second horizontal direction, such that the bit lines intersect with a source/drain region of the plurality of channels, and the word lines intersect with gate regions of the plurality of channels. Arrays include where the source/drain region includes a low bandgap material, where the low bandgap material exhibits a bandgap less than a bandgap of a channel material.

### CROSS-REFERENCES TO RELATED APPLICATIONS

This application claims the benefit of priority to U.S. Patent Application No. 63/619,180 filed Jan. 9, 2024, the contents of which are hereby incorporated by reference in their entirety for all purposes.

### TECHNICAL FIELD

This disclosure generally describes designs for advanced DRAM, such as 4F² dynamic random access memory (DRAM) arrays and/or 3D DRAM. More specifically, this disclosure describes an advanced DRAM memory array with a decreased floating body effect and improved retention time.

### BACKGROUND

With advances in computing technology, computing devices are smaller and have increased processing power. Accordingly, increased storage and memory is needed to meet the devices' programming and computing needs. The shrinking size of the devices with increased storage capacity is achieved by increasing the number of storage units having smaller geometries.

Dynamic random-access memory (DRAM) architectures continue to scale down over time. For example, a one transistor, one capacitor (1T-1C) DRAM cell architecture has successfully scaled down from an 8F² size to a 6F² size (where F is the minimum feature size). Further design scheme changes from 6F² to 4F² may help further improve area density. In the 4F² DRAM scheme, a storage node (capacitor) and bit line are located at the top and bottom of a vertical cell transistor, leaving the channel completely isolated from the body. Due to this arrangement, the floating body effect, which is not an issue for current 8F² or 6F² DRAM cell architecture due to the body connection of the channels, becomes a major technical challenge for 4F² DRAM. Therefore, improvements in the art are needed.

### BRIEF SUMMARY

The present technology is generally directed to vertical cell dynamic random-access memory (DRAM) arrays. Arrays include one or more bit lines arranged in a first horizontal direction, one or more word lines arranged in a second horizontal direction, and one or more channels extending in a vertical direction that is generally orthogonal to the first horizontal direction and the second horizontal direction such that the one or more bit lines intersect with a source/drain region of the one or more channels, and the one or more word lines intersect with a gate region of the one or more channels. Arrays include where the source/drain regions contain a low bandgap material, where the low bandgap material exhibits a bandgap less than a bandgap of a channel material. Arrays include where the source/drain region contain silicon germanium.

In embodiments, germanium is present in the silicon germanium in an amount of about 5 wt. % to about 60 wt. %. In further embodiments, the source/drain region includes a first section adjacent to the one or more channels and a second section opposite the first section, where the second section has a higher concentration of dopant than the first section. Moreover, in embodiments, the second section has a dopant concentration that is at least about 2 times higher than a dopant concentration of the first section. Additionally or alternatively, in embodiments, the source/drain region comprises a drain region or a source region. Embodiments include where both the source and the drain contain the low bandgap material. Furthermore, in embodiments, the gate region comprises a single gate, a double gate, or encircles the respective channel. In yet more embodiments, the low bandgap material exhibits a bandgap that is less than or about 1 eV. In embodiments, the low bandgap material exhibits a bandgap that is at less than or about 10% of the bandgap of the channel material.

The present technology is also generally directed to methods of forming vertical cell dynamic random-access memory (DRAM) arrays. Methods include forming a substrate that includes a low bandgap material layer over a substrate material, and one or more channel materials disposed over the low bandgap material layer. Methods include etching the substrate to form one or more shallow trench isolations and a plurality of vertically extending channels having at least a first source/drain region. Methods include where the first source/drain region is formed from the low bandgap material layer, and the low bandgap material exhibits a bandgap less than a bandgap of the channel material.

In embodiments, the low bandgap material layer exhibits a doping gradient extending from a contact region to a channel region. In more embodiments, the low bandgap material layer is formed over the substrate material by epitaxial growth, and a dopant concentration is increased or decreased during formation of the low bandgap material layer, forming the doping gradient. Furthermore, embodiments, include additionally doping the low bandgap material layer, forming at least a portion of the doping gradient. Additionally or alternatively, embodiments include where the low bandgap material layer contains silicon germanium, where germanium is present in the silicon germanium in an amount of about 5 wt. % to about 60 wt. %.

The present technology is also generally directed to methods of forming vertical cell dynamic random-access memory (DRAM) arrays. Methods include etching a substrate to form one or more shallow trench isolations and a plurality of vertically extending channels. Methods include contacting one or more of the plurality of vertically extending channels with a low bandgap dopant, forming a first source/drain region. Methods include forming a second source/drain region. Methods include where the low bandgap material exhibits a bandgap less than a bandgap of a channel material.

In embodiments, the first source/drain region is formed by contacting the one or more vertically extending channels with the dopant by plasma doping, gas phase doping, or a combination thereof. In further embodiments, methods include annealing the one or more doped vertically extending channels. Moreover, embodiments include where the plasma doping, gas phase doping, or combination thereof includes a germanium dopant, where germanium is present in the silicon germanium in an amount of about 5 wt. % to about 60 wt. % after contacting. In yet more embodiments, at least a portion of one or more of the plurality of vertically extending channels includes silicon germanium prior to the contacting.

Such technology may provide numerous benefits over conventional systems and techniques. For example, the processes and systems may reduce the floating body effect, as well as improved retention time over time. Additionally, the processes and systems may significantly improve gate-induced drain leakage, such as by providing a lower bandgap material at a source/drain region as compared to the channel. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1A shows a top plan view of an exemplary processing chamber according to embodiments of the present technology.

FIG. 1B illustrates a top view of a conventional 4F² memory array.

FIG. 1C illustrates a perspective view of a conventional 4F² memory array.

FIG. 2 shows selected operations in a formation method according to embodiments of the present technology.

FIG. 3A shows a perspective view of a precursor semiconductor structure according to embodiments of the present technology with a sacrificial layer formed over a substrate.

FIG. 3B shows a perspective view of a precursor semiconductor structure according to embodiments of the present technology with a junction formed over a sacrificial layer.

FIG. 3C shows a perspective view of a precursor semiconductor structure according to embodiments of the present technology with a channel formed over the junction.

FIG. 4A shows a perspective view of a semiconductor structure according to embodiments of the present technology.

FIG. 4B shows a perspective view of a semiconductor structure according to embodiments of the present technology.

FIG. 4C shows a perspective view of a semiconductor structure according to embodiments of the present technology.

FIG. 4D shows a perspective view of a semiconductor structure according to embodiments of the present technology.

FIG. 4E shows a perspective view of a semiconductor structure according to embodiments of the present technology.

FIG. 5 shows cross sectional illustration of a junction according to embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Historically, DRAM chip bit densities have been increasing by approximately 25% node over node. However, the node over node increase in bit density has trended down to closer to 20% for the more recent generations, mainly due to the challenges with scaling the cell area. Cell design architecture for modern DRAM technology has been based on 6F² geometry, where “F” is the minimum feature size for a given technology node. Switching from 6F² to 4F² cell architecture could result in a 33% increase in bit density at the same technology node. In addition, patterning difficulties for 4F² DRAM are greatly reduced as compared to 6F². This is due at least in part to the fact that in the 4F² DRAM scheme, the capacitor and bit line are located at two ends of a vertical cell transistor, instead of tightly packed on the same side as in 6F² DRAM.

However, advanced DRAM structures, including vertical cell structures such as 4F² DRAM or 3D DRAM, as examples, come with their own challenges. For example, 4F² and 3D DRAM memory cells have the transistor channel disposed between the bitline and the capacitor layers, leaving no common substrate connecting the channels, resulting in a floating body effect for these transistors. For instance, it is believed that advanced DRAM access devices exhibit off-leakage current issues. Off-leakage current results from the floating body effect, such as hole accumulation in the body of an advanced DRAM device due to the isolated channels. Electron-hole pairs can form in a semiconductor channels due to band-to-band tunneling. While the electrons can flow into the n-type source or drain regions of the transistor, the holes cannot. For advanced DRAM devices without a substrate connection, the holes have no path to leave the channel and will continue to accumulate. Thus, the floating body effect may lead to channel activation without gate activation, which eventually translates into leakage current from the capacitor, or data storage side of the device, as well as into degradation of the threshold voltage (and thus retention time) over time. Attempts have been made to provide body connections utilizing a buried body contact scheme. However, such attempts can result in gate overlap to a source/drain junction edge, allowing undesired gate-induced drain leakage, or limited scalability to small dimensions. Moreover, such design schemes are also capable of producing high aspect ratio structures that challenge existing doping techniques.

Due at least in part to the floating body effect, advanced DRAM, including vertical channel access array transistors (VCAATs), are more susceptible to elevated leakage current values, such as gate induced drain leakage. This phenomena may further exacerbate the floating body effect. For instance, as holes continue to accumulate, charge may accumulate on the bit line, reducing the potential between the channel and the storage node. This may allow increased band-to-band tunneling, and further decrease the threshold voltage of the access transistor.

The present technology overcomes these and other problems by providing one or more source/drain regions formed from a low bandgap material that provides a valence offset from the channel material. Namely, by carefully controlling the formation of one or more source/drain regions, the valence offset formed by the low bandgap material may provide for improve movement of holes from the channel. Due at least in part to improved hole movement out of the device, devices discussed herein may exhibit a drastically reduced floating body effect, reducing the leakage current and improving retention time. Thus, unlike prior attempts, the present technology may provide a word line that maintains a necessary threshold voltage for low off current leakage while reducing the gate induced drain leakage, and even the floating body effect of advanced DRAM devices.

Although the remaining disclosure will routinely identify specific deposition and etch processes utilized for forming vertical cell access array transistors (VCAATs), such as a 4F² DRAM device and/or 3D DRAM device, it will be readily understood that the systems and methods are equally applicable to other DRAM devices, including gate-all-around and Schottky barrier VCAATs, other devices suffering from a floating body effect, and orientations thereof, as well as processes for forming such devices. Accordingly, the technology should not be considered to be so limited as for use with these specific devices or systems alone. The disclosure will discuss one possible semiconductor device that may include one or more components, utilizing one or more word lines according to embodiments of the present technology before additional variations and adjustments to this apparatus according to embodiments of the present technology are described.

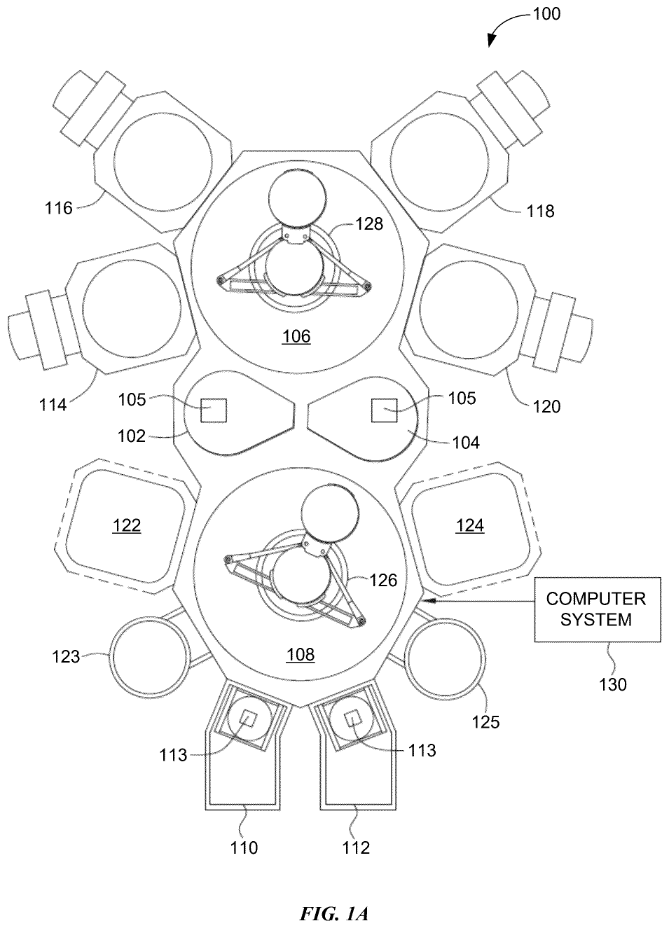

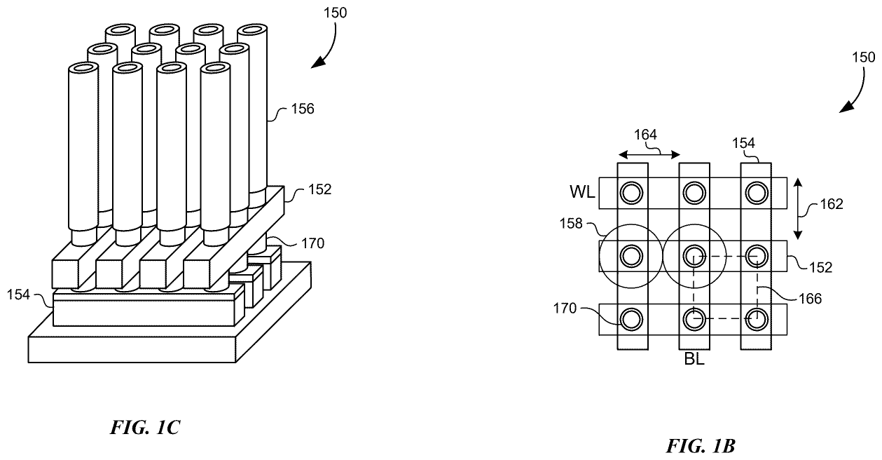

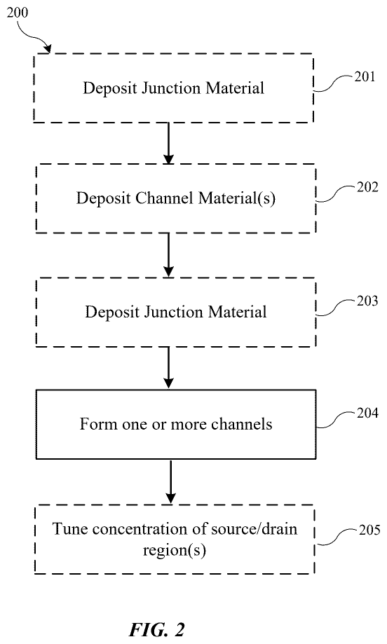

FIG. 1A illustrates a top plan view of a multi-chamber processing system 100, which may be specifically configured to implement aspects or operations according to some embodiments of the present technology. The multi-chamber processing system 100 may be configured to perform one or more fabrication processes on individual substrates, such as any number of semiconductor substrates, for forming semiconductor devices. The multi-chamber processing system 100 may include some or all of a transfer chamber 106, a buffer chamber 108, single wafer load locks 110 and 112, although dual load locks may also be included, processing chambers 114, 116, 118, 120, 122, and 124, preheating chambers 123 and 125, and robots 126 and 128. The single wafer load locks 110 and 112 may include heating elements 113 and may be attached to the buffer chamber 108. The processing chambers 114, 116, 118, and 120 may be attached to the transfer chamber 106. The processing chambers 122 and 124 may be attached to the buffer chamber 108. Two substrate transfer platforms 102 and 104 may be disposed between transfer chamber 106 and buffer chamber 108, and may facilitate transfer between robots 126 and 128. The platforms 102, 104 can be open to the transfer chamber and buffer chamber, or the platforms may be selectively isolated or sealed from the chamber to allow different operational pressures to be maintained between the transfer chamber 106 and the buffer chamber 108. Transfer platforms 102 and 104 may each include one or more tools 105, such as for orientation or measurement operations.

The operation of the multi-chamber processing system 100 may be controlled by a computer system 130. The computer system 130 may include any device or combination of devices configured to implement the operations described below. Accordingly, the computer system 130 may be a controller or array of controllers and/or a general purpose computer configured with software stored on a non-transitory, computer-readable medium that, when executed, may perform the operations described in relation to methods according to embodiments of the present technology. Each of the processing chambers 114, 116, 118, 120, 122, and 124 may be configured to perform one or more process steps in the fabrication of a semiconductor structure. More specifically, the processing chambers 114, 116, 118, 120, 122, and 124 may be outfitted to perform a number of substrate processing operations including dry etch processes, cyclical layer deposition, atomic layer deposition, chemical vapor deposition, physical vapor deposition, etch, pre-clean, degas, orientation, among any number of other substrate processes.

FIGS. 1B and 1C illustrate top and perspective views of a conventional 4F² memory array 150. The memory array 150 may include a plurality of word lines 152 that are arranged in a first layer over a substrate. The word lines 152 may be conductive traces that are used to select a word line of memory cells in the memory array 150. The memory array 150 may also include a plurality of bit lines 154 arranged in a second layer over a substrate. The plurality of bit lines may be conductive traces that are used to select a bit line of memory cells in the memory array 150. Activating one of the plurality of bit lines 154 and one of the plurality of word lines 152 may select an individual cell in the memory array 150. The first layer and the second layer may include different metal layers formed at different times during manufacturing process. For example, the first layer with the word lines 152 may be formed above the second layer with the bit lines 154 such that the two layers do not intersect.

A plurality of vertical memory cells may be arranged over intersections between the plurality of word lines 152 and the plurality of bit lines 154. Each of the plurality of vertical memory cells may include a vertical transistor, which may be referred to as a vertical pillar transistor or vertical column transistor. A channel material for the transistor may be formed from a single-crystal silicon pillar, or any other substrates discussed in greater detail below. This silicon channel may be formed by etching the substrate. Each of the plurality of vertical memory cells may also include a vertical capacitor 156. The vertical memory cell may operate by storing a charge on the vertical capacitors 156 to indicate a saved memory state. However, while FIGS. 1B and 1C illustrate the arrangement of the vertical transistors and capacitors in a rectangular generally orthogonal grid pattern (where “generally orthogonal” may be within about 10° from orthogonal, such as less than or about 7.5°, such as less than or about 5°, such as less than or about 2.5°, such as less than or about 1° from orthogonal, or any ranges or values therebetween, where “generally” may be utilized to similarly vary “vertical”, “horizontal” and the like), it should be understood that other orientations are contemplated for use with the present technology. For instance, in embodiments, the capacitors and vertical transistors may be spaced in alternating rows that are offset by one half the distance between the vertical transistors. Namely, a first row of memory cells may be regularly spaced apart in a line in a first direction, and a second row of memory cells may also be regularly spaced apart in a line also in the first direction, but the second row of memory cells may be offset from the first row of memory cells, such as aligned approximately halfway between the vertical transistors and capacitors of the first row, in embodiments. Such a pattern may be referred to as a “honeycomb” or “hexagonal pattern” as compared to the square pattern illustrated in FIGS. 1B and 1C. Thus, it should be understood that any suitable orientation may be utilized with the present technology.

It is useful to characterize the dimensions of the unit cell area 166 for this conventional 4F² memory array for comparison to the simple memory array described below. For example, a capacitor footprint 158 may be defined as a circular area around each vertical capacitor 156. The capacitor footprint 158 may include the horizontal cross-sectional area of the capacitor expanded out until the cross-sectional area contacts a capacitor area from a neighboring memory cell. Assuming that the word line pitch 162 for the plurality of word lines 152 and the bit line pitch 164 for the plurality of bit lines 154 may be defined as 2F. This leads to an overall cross-sectional area of 4F² for a unit cell area 166.

FIG. 2 shows exemplary operations in a method 200 according to some embodiments of the present technology. The method may be performed in a variety of processing chambers, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. In addition, while the method may describe the formation method vertically, it should be understood that the other orientation from bit line to word line side may be utilized.

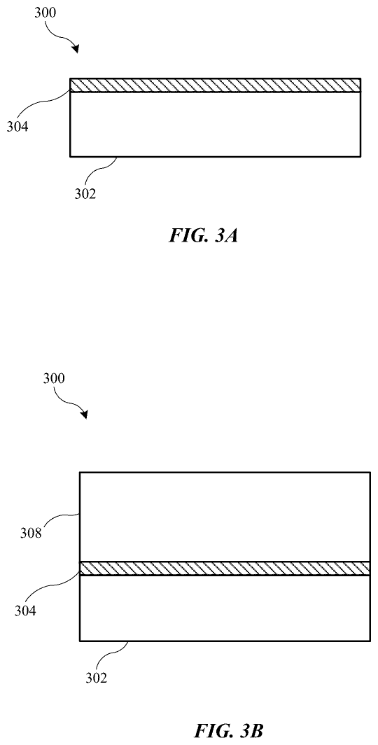

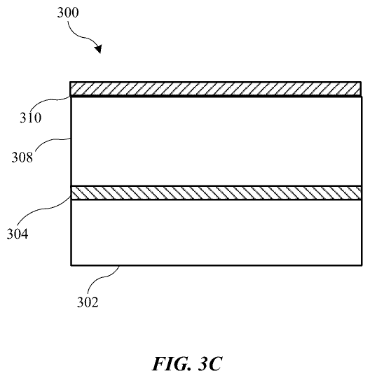

Method 200 may include additional operations prior to initiation of the listed operations. For example, additional processing operations may include forming structures on a semiconductor substrate, which may include both forming and removing material. Prior processing operations may be performed in the chamber in which method 200 may be performed, or processing may be performed in one or more other processing chambers prior to delivering the substrate into the semiconductor processing chamber in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support/transfer platform, which may be a pedestal such as substrate support 104, and which may reside in a processing region of the chamber, such as processing region of processing chamber 120 described above. Method 200 describes operations shown schematically in FIGS. 3A-3C, 4A-4E, and 5, the illustrations of which will be described in conjunction with the operations of method 200. It is to be understood that FIGS. 3A-3C, 4A-4E, and 5 illustrate only partial schematic views, and a semiconductor substrate may include further components as illustrated in the figures, as well as alternative components, of any size or configuration that may still benefit from aspects of the present technology.

Method 200 may or may not involve optional operations to develop the semiconductor structure to a particular fabrication operation. It is to be understood that method 200 may be performed on any number of semiconductor structures 300 or substrates 302, as illustrated in 3A-3C, 4A-4E, and 5, including exemplary structures on which a selective deposition material may be formed. As illustrated in FIG. 3A substrate 302 may be any number of materials, such as a base wafer or substrate made of silicon or silicon-containing materials, germanium, other substrate materials, as well as one or more materials that may be formed overlying the substrate during semiconductor processing.

Moreover, while various deposition and fill processes will be described, it should be understood that, in embodiments, the semiconductor structure may be transferred to and between one or more process chambers 114, 116, 118, 120, 122, and 124 configured for deposition and/or fill processes, including chambers for: chemical vapor deposition (CVD), physical vapor deposition (PVD), atomic layer deposition (ALD), thermally enhanced chemical vapor deposition (CVD), plasma-enhanced chemical vapor deposition (PECVD), plasma enhanced atomic layer deposition (PEALD), or the like. Thus, unless specified, it should be understood that any one or more of the above methods may be utilized as known in the art. Similarly, the semiconductor structure may be transferred to and between one or more process chambers 114, 116, 118, 120, 122, and 124 configured for etching, such as one or more of inductively coupled plasma (ICP) etching, reactive ion etching (RIE), capacitively coupled plasma (CCP) etching, or the like, as well as other etching processes as known in the art.

In embodiments, the substrate 302 may include bulk substrates, epitaxially grown substrates, and/or silicon on insulator wafer. As used herein, the term “semiconductor substrate” refers to a substrate in which the entirety of the substrate is comprised of a semiconductor material. The semiconductor substrate may include any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In embodiments, the semiconductor material is silicon (Si). In one or more embodiments, the semiconductor substrate 300 includes a semiconductor material, e.g., silicon (Si), carbon (C), germanium (Ge), silicon germanium (SiGe), germanium tin (GeSn), other semiconductor materials, or any combination thereof. In one or more embodiments, the substrate 302 includes one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In embodiments, the semiconductor material may be a doped material, such as n-doped silicon (n-Si), or p-doped silicon (p-Si). In embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers.

As illustrated in FIG. 3A, structure 300 is provided that includes a substrate 302 that has a junction layer 304 formed thereon at operation 201. In embodiments, the junction layer 304, also referred to as a “a source/drain material” may be deposited or grown over substrate 302 in any manner as known in the art. As will be discussed in greater detail below, the junction layer 304 may be one or more materials having a lower band gap than substrate 302 material. For instance, in embodiments, the junction layer 304 may have a band gap of less than 1.1 eV, such as less than or about 1.05 eV, such as less than or about 1 eV, such as less than or about 0.95 eV, such as less than or about 0.9 eV, such as less than or about 0.85 eV, such as less than or about 0.8 eV, such as less than or about 0.75 eV, such as less than or about 0.7 eV, such as less than or about 0.6 eV, or any ranges or values therebetween.

Stated differently, in embodiments, the junction layer material may have a bandgap that is less than or about 5% of a bandgap of the channel material, such as less than or about 10%, such less than or about 15%, such as less than or about 20%, such as less than or about 25%, such as less than or about 30%, such as less than or about 35%, such as less than or about 40%, such as less than or about 45%, such as less than or about 50%, such as less than or about 55%, such as less than or about 60% of a bandgap of the channel material, or any ranges or values therebetween. While other materials may be discussed below, in embodiments, the junction layer 304 may include silicon germanium, which may also be referred to herein as germanium doped silicon when referring to the weight percentage of germanium present.

Namely, the present technology has surprisingly found that by forming a semiconductor structure 300 according to the methods and disclosure herein, the semiconductor structure 300 may be uniquely formed to allow for the formation of one or more source/drain regions on a structure 300 that provide for the movement of holes from the channel body. Namely, by initially forming a junction layer 304, the junction layer 304 may be formed from one or more materials not achievable by doping the channel material alone. However, as will be discussed in greater detail below, in embodiments, the source/drain region discussed herein may be obtained through one or more doping operations after formation of the one or more vertical channels.

In embodiments, a dopant may be utilized to obtain the low bandgap material, and may be incorporated into the junction layer in an amount based upon the desired bandgap of the material. For instance, when SiGe is utilized as the junction layer 304 material, the germanium may be present in an amount of about 5 wt. % or greater, based upon the weight of the silicon and germanium in the SiGe, such as greater than or about 7.5 wt. %, such as greater than or about 10 wt. %, such as greater than or about 12.5 wt. %, such as greater than or about 15 wt. %, such as less than or about 25 wt. %, such as less than or about 22.5 wt. %, such as greater than or about 25 wt. %, such as greater than or about 27.5 wt. %, such as greater than or about 30 wt. %, such as greater than or about 32.5 wt. %, such a greater than or about 35 wt. %, such as greater than or about 37.5 wt. %, such as greater than or about 40 wt. %, such as greater than or about 42.5 wt. %, such as greater than or about 45 wt. %, such as greater than or about 47.5 wt. %, such as greater than or about 50 wt. %, such as greater than or about 52.5 wt. %, such as greater than or about 55 wt. %, such as greater than or about 57.5 wt. %, such as up to about 60 wt. %, or such as less than or about 60 wt. %, such as less than or about 55 wt. %, such as less than or about 50 wt. %, such as less than or about 45 wt. %, such as less than or about 40 wt. %, such as less than or about 35 wt. %, such as less than or about 30 wt. %, such as less than or about 25 wt. %, such as less than or about 20 wt. %, such as less than or about 15 wt. %, such as less than or about 10 wt. %, such as less than or about 7.5 wt. %, or any ranges or values therebetween. However, it should be clear that the above percentages may be applicable to other dopants utilized to obtain the low bandgap material discussed herein.

Nonetheless, as the junction layer 304 will serve as a source/drain region for contacting the bitline or storage node contact, the thickness or height of the junction layer 304 may be selected based upon the desired thickness or height of the resulting feature. Thus, in embodiments, the junction layer 304 may be deposited or grown to a thickness (height) of greater than or about 5 nm, such as greater than or about 10 nm, such as greater than or about 15 nm, such as greater than or about 20 nm, such as greater than or about 25 nm, such as greater than or about 30 nm, such as greater than or about 35 nm, such as greater than or about 40 nm, or such as less than or about 60 nm, such as less than or about 55 nm, such as less than or about 50 nm, such as less than or about 45 nm, such as less than or about 40 nm, or any ranges or values therebetween.

Namely, the present technology has found that by growing the film layer, a junction may be formed from silicon germanium, such as by epitaxial growth, on semiconductor structure 300. Such as process may be advantageous, as it removes the necessity for doping the junction after formation of one or more channels (discussed in greater detail below) or as part of backside processing.

Furthermore, the present technology has found that by forming one or more junction layers during deposition or growth of the structure, a targeted and highly consistent level of dopant may be formed without requiring later junction processing. For instance, in embodiments, a junction material 304 may have a dopant concentration at any point along or within the junction layer 304 that is greater than or about 50% of a target doping concentration of junction layer 304, such as greater than or about 60%, such as greater than or about 70%, such as greater than or about 80%, such as greater than or about 85%, such as greater than or about 90%, such as greater than or about 92.5%, such as greater than or about 95%, such as greater than or about 97.5%, such as greater than or about 99%, such as greater than or about 99.5% of the average doping concentration of junction layer 304, or any ranges or values therebetween.

However, it should be clear that the, in embodiments, the target doping concentration may vary when travelling in a direction from substrate 302 towards channel material 308 (e.g. such as decrease, in embodiments). Thus, in embodiments, the highly consistent doping level may be in comparison to a target doping level in a corresponding horizontally extending layer of junction material. For instance, the present technology has surprisingly found that by forming the junction as part of a precursor structure 300, a respective layer or portion of the junction may have a highly consistent doping concentration and may exhibit little to no variation across the layer. Furthermore, the highly accurate doping is exhibited within a respective region or portion even when changing the target doping concentration as the junction is formed in a vertical direction. Thus, in embodiments, the above discussed values may be in relation to a point within a respective junction layer having a dopant concentration consistent with a target doping concentration for the respective layer or portion.

In embodiments, a channel material 308 may be deposited over junction layer 304 at operation 202 as illustrated in FIG. 3B. In embodiments, the channel material 308 may be deposited directly over junction layer 304 (e.g., no intervening layers between junction layer 304 and channel material 308) or may be deposited over one or more intervening layers (not shown). Nonetheless in embodiments, the channel material 308 may be any one or more of the substrate materials discussed above and may be individual selected to be the same or different than a material forming substrate 302 and/or junction layer 304.

In embodiments, channel material layer 308 may be formed from the same material as junction layer 304, except that no dopant, or only very small levels, may be present. Thus, in such an embodiment, if epitaxial growth is utilized, the epitaxial growth may continue uninterrupted during the formation of junction layer 304 and channel material 308, but no, or only very small levels, of dopant may be incorporated during growth of channel material 308. Nonetheless, as discussed above, in embodiments, other deposition methods may be utilized, such that a different material, a different process, or a combination thereof, occurs between junction layer 304 and channel material 308. Regardless, in embodiments, the channel material 308 may be epitaxial grown silicon (or any of the other substrate materials discussed above) with a lower amount, or no, dopant present in the layer, forming a material having a higher bandgap that junction layer 304.

In embodiments, regardless of the material selected, the channel may be deposited to a height corresponding to a desired channel length. Thus, in embodiments, the channel may be deposited to a height, measured from junction layer 304 to an top end surface of channel material 308, of greater than or about 10 nm, such as greater than or about 15 nm, such as greater than or about 20 nm, such as greater than or about 25 nm, such as greater than or about 30 nm, such as greater than or about 35 nm, such as greater than or about 40 nm, such as greater than or about 45 nm, such as greater than or about 50 nm, such as greater than or about 55 nm, such as greater than or about 60 nm, such as greater than or about 65 nm, such as greater than or about 70 nm, such as greater than or about 75 nm, such as greater than or about 80 nm, such as greater than or about 90 nm, such as greater than or about 100 nm, such as greater than or about 120 nm, such as greater than or about 140 nm, such as greater than or about 160 nm, such as greater than or about 180 nm, such as greater than or about 200 nm, such as greater than or about 220 nm, such as greater than or about 240 nm, or such as greater than or about 250 nm, or such as less than or about 250 nm, such as less than or about 200 nm, such as less than or about 150 nm, such as less than or about 100 nm, or any ranges or values therebetween.

In embodiments, a second junction material 310 may be grown or deposited over channel material 308 at operation 203, as illustrated in FIG. 3C. In embodiments, the second junction material 310 may be grown or deposited directly over channel material layer 308 (e.g., no intervening layers between channel material layer 308 and second junction material 310) or may be grown or deposited over one or more intervening layers (not shown). Nonetheless in embodiments, the second junction material 310 may be any one or more of the substrate materials discussed above and may be individual selected to be the same or different than a material forming substrate 302, junction layer 304, and/or channel material layer 308.

Furthermore, in embodiments, second junction material 310 may be formed from the same material as junction layer 304. Thus, in such an embodiment, if epitaxial growth is utilized, the epitaxial growth may continue uninterrupted during the formation of junction layer 304, channel material layer 308, and second junction material 310 but germanium may be incorporated during the junction layer 304 and second junction material 310, but not during formation of channel material layer 308. Nonetheless, as discussed above, in embodiments, other deposition methods may be utilized, such that a different material, a different process, or a combination thereof, occurs between one or more of first channel material layer 308, channel material layer 308, and second junction material 310. Regardless, in embodiments, the second junction material 310 may be epitaxial grown silicon (or any of the other substrate materials discussed above) with an amount of germanium similar to, or generally equal to, junction layer 304. Regardless, such a substrate formation process (or provided substrate therefrom) may allow for high aspect ratio structures or features, or other complex features (e.g., one or more turns or bends from a central access hole) to be obtained with highly consistent and targeted germanium levels difficult to achieve using conventional processes.

However, in embodiments, the one or more channel material layers 308 may instead be formed of one material, such as any one or more of the substrate materials discussed above. In such an embodiments, the one or more channel material layers 308 may undergo source/drain formation as known in the art. Such as by utilizing one or more implants after formation of a trench isolation 414, discussed in greater detail below. Additionally or alternatively, only one junction material layer may be formed during formation of the precursor structure, and the first or second junction layer may be formed during further processing, such as by junction doping, implant and anneal processes, or the like. For instance, in embodiments, the source or drain region may be formed from one or more junction materials discussed above, and the opposite source or drain region is formed by traditional source/drain formation methods. In such embodiments, one or more further layers may be formed over section junction layer 310, such as one or more materials utilized to form a contact pad, or other features as needed.

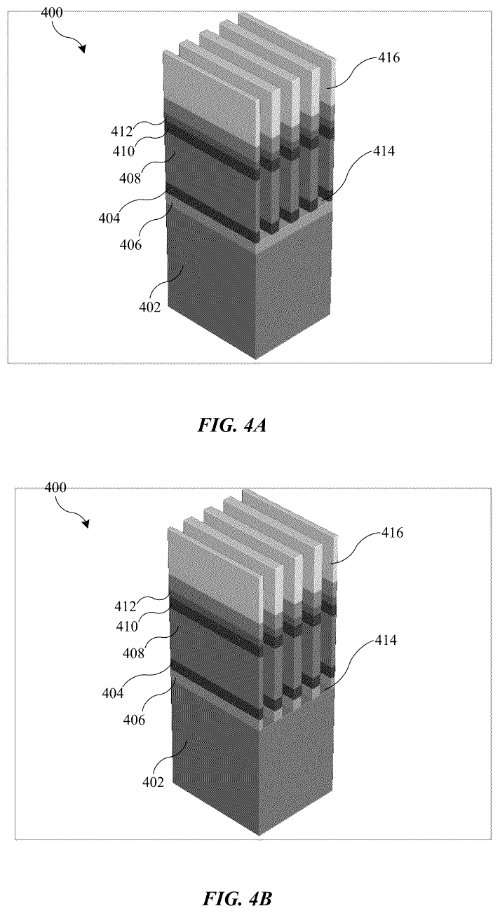

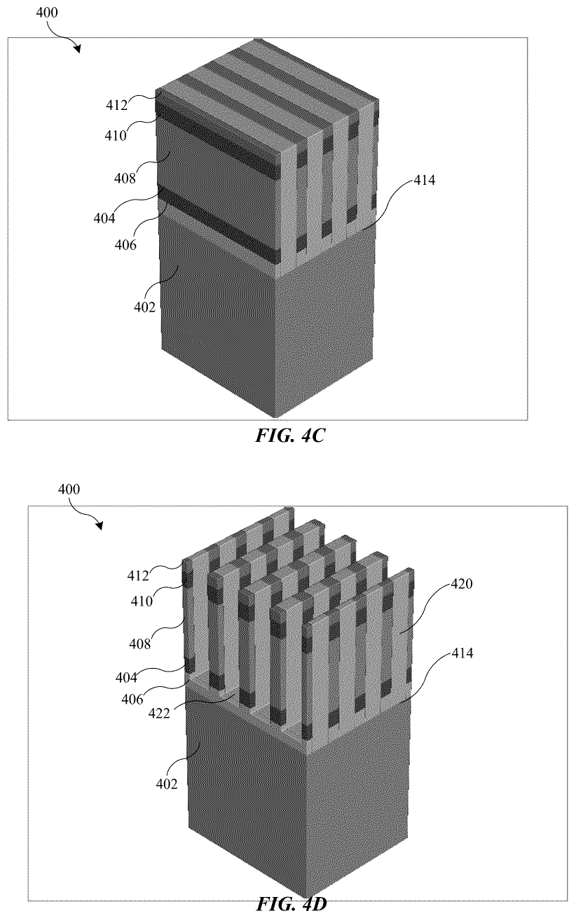

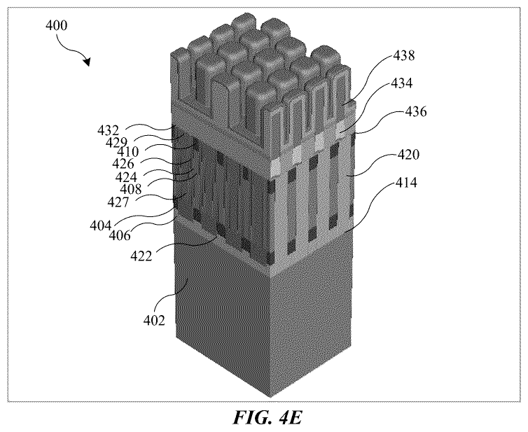

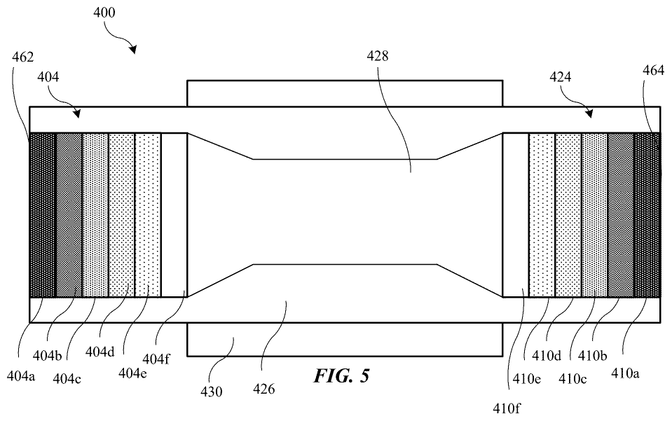

While it should be clear that the precursor semiconductor structure 300 may be utilized to advantageously form a variety of challenging structures, FIGS. 4A-4E and 5 may illustrate exemplary structures, and methods of forming such structures, utilizing the precursor semiconductor structure 300 for illustration only. However, it should be clear that these examples are non-limiting and that further structures as well as methods of forming such structures from the precursors discussed above are contemplated, such as any one or more advanced DRAM structures. In addition, as discussed above, it should be clear that, in embodiments, no precursor structure is utilized, and instead the source/drain regions are formed after patterning of one or more vertical channels.

Nonetheless, as illustrated in FIG. 4A, structure 400 may have one or more trench isolations 414 formed through junction material 404, channel material 408, and second junction material 410. Such a trench may be formed as known in the art, such as by patterning and etching, such as by utilizing mask 416 and any etching process known in the art. As illustrated in FIGS. 4A and 4B, a sacrificial material 406 may be included between the substrate 402 and first junction material 404. Namely, such a sacrificial material may allow adjacent channels to be separated, preventing the likelihood of shorting (e.g. such as by a further etching operation as illustrated in FIG. 4B). However, in embodiments, no sacrificial material may be necessary, as a “bottom punch” etch, such as a reactive ion etch, may be utilized to remove portions of the junction material 404 between adjacent channels.

As discussed above, in embodiments, source/drain region 304 and/or 310 is conducted by growing one or more of the junction regions during precursor formation. However, in embodiments, it may be desired to form one or more of the source/drain regions 404 and/or 410 after etching the one or more trenches. Additionally or alternatively, it may be desired to further tune the concentration of the low band gap material in the respective region at optional operation 205. Thus, operation 205 may include doping one or more of the junction regions with the same low band gap material, or a different low band gap material. Doping operations may include gas phase doping, plasma doping, combinations thereof, and the like, as known in the art. In addition, one or more doping operations may be conducted. When multiple doping operations are utilized, each implant may utilize the same ion, or different ions.

Although, it should be understood that the source/drain region 404 and/or 410 may be formed from any suitable process, in embodiments, source/drain region 404 and/or 410 may be imparted with one or more doping gradients, which will be discussed in greater detail in regards to FIG. 5. In embodiments, the present technology has found that by utilizing a doping gradient for the first source/drain regions 404 and/or second source/drain region 410, the formed source/drain region(s) may have few defects and may exhibit further improved movement of holes out of the channel.

In embodiments, the one or more source/drain regions (or junction layer(s) discussed above) are only formed in a portion of one or more channels 348. For instance, as illustrated in FIG. 4B, the one or more source/drain regions have a height that is from about 5% to about 30% of a height of the respective channel 348, such as greater than or about 7.5%, such as greater than or about 10%, such as greater than or about 12.5%, such as greater than or about 15%, such as greater than or about 17.5%, such as greater than or about 20%, such as greater than or about 22.5%, such as greater than or about 25%, such as greater than or about 27.5%, or such as less than or about 30%, such as less than or about 27.5%, such as less than or about 25%, such as less than or about 22.5%, such as less than or about 20%, or any ranges or values therebetween.

Stated differently, in embodiments, the height of the one or more source/drain regions may be greater than or about 2 nm, such as greater than or about 4 nm, such as greater than or about 6 nm, such as greater than or about 8 nm, such as greater than or about 10 nm, such as greater than or about 12 nm, such as greater than or about 14 nm, such as greater than or about 16 nm, such as greater than or about 18 nm, such as greater than or about 20 nm, such as greater than or about 22 nm, such as greater than or about 24 nm, such as greater than or about 26 nm, such as greater than or about 28 nm, such as greater than or about 30 nm, such as greater than or about 32 nm, such as greater than or about 34 nm, such as greater than or about 36 nm, such as greater than or about 38 nm, such as greater than or about 40 nm, or such as less than or about 70 nm, such as less than or about 60 nm, such as less than or about 50 nm, such as less than or about 55 nm, such as less than or about 50 nm, such as less than or about 45 nm, such as less than or about 40 nm, or any ranges or values therebetween.

Nonetheless, in embodiments, one or more of the first source/drain regions 404 and/or second source/drain regions 410 may be formed to exhibit a doping gradient, as shown more clearly in FIG. 5, which may illustrate a cross-sectional illustrate of one or more channel regions discussed herein. In embodiments, the first source/drain region 404, second source/drain region 410, or both the first source/drain region 404 and second source/drain region 410 may have a first section 404a/410a adjacent to an end surface such as bitline 462 and/or storage node contact 464 of the channel 448. The first section 404a/410a exhibits a higher doping concentration than the other sections, such as all of the other sections, of source/drain region 404/410. In embodiments, the first section of the respective source/drain region may be directly adjacent to the end surface such as bitline 462 and storage node contact 464 of the respective channel and may form all or portion of the end surface (e.g. may form a source/drain junction).

Reference character 424 denotes the gate oxide of the transistor that might be single layer or multi-layer formed of single or multiple dielectric layers. The one or more gate oxide layers can include SiO2, SiON, SiN, HfO2, HfZrO, different doping of HfOx, other oxides as known in the art, and combinations thereof. While the figures are shown in cross-section, in embodiments, gate oxide 424 may extend around channel 448, for example, in a gate-all-around structure, or may extend along only a single side of each channel in a single gated orientation, or may be a double gated orientation.

Furthermore, opposed end regions, illustrated by section 404f/410f in FIG. 5 may be disposed adjacent to the gate 430 of the transistor which doubles as a wordline 430, and may form an interface with the wordline 430. In embodiments, the sections adjacent to the channel body may have a lower doping concentration than the other sections, such as all of the other sections, of source/drain region 404/410. While the figures are shown in cross-section, it should be understood that in embodiments, wordline 430 may extend around channel 448, for example, in a gate-all-around structure, or according to any one or more of the gate orientations discussed above.

Nonetheless, in embodiments, all or a portion of first section 404a and/or 410a may have a doping concentration of greater than or about 10 wt. % dopant based on the weight of the section, such as greater than or about 12.5 wt. %, such as greater than or about 15 wt. %, such as greater than or about 17.5 wt. %, such as greater than or about 20 wt. %, such as greater than or about 25 wt. %, such as greater than or about 30 wt. %, such as greater than or about 35 wt. %, such as greater than or about 40 wt. %, such as greater than or about 45 wt. %, such as greater than or about 50 wt. %, such as greater than or about 55 wt. %, such as up to about 60 wt. %, or any ranges or values therebetween. In embodiments, end surface 462 and/or 464 may exhibit any one or more of the above concentrations as well as the doping levels discussed above in regards to the one or more junction material layers, and the concentration may decrease moving away from end surface 462/464 towards channel body 428.

Furthermore, in embodiments, all or a portion of section 404f and/or 410f may have a doping concentration of less than or about 20 wt. %, such as less than or about 17.5 wt. %, such as less than or about 15 wt. %, such as less than or about 12.5 wt. %, such as less than or about 10 wt. %, such as less than or about 9 wt. %, such as less than or about 8 wt. %, such as less than or about 7 wt. %, such as less than or about 6 wt. %, such as less than or about 5 wt. %, such as less than or about 4 wt. %, such as less than or about 3 wt. %, such as less than or about 2 wt. %, such as less than or about 1 wt. %, or any ranges or values therebetween. In embodiments, regardless of the doping concentration, section 404f and/or 410f may have a doping concentration that is less than section 404a and/or 410a.

Thus, in embodiment, first section 404a and/or 410a may have a doping concentration that is higher than a doping concentration of section 404f and/or 410f. In embodiments, first section 404a and/or 410a adjacent to one or more ends 462/464 may have a doping concentration that is at greater than or about 1.5 times higher than a doping concentration of section 404f and/or 410f adjacent to channel body 428, such as greater than or about 2 times, such as greater than or about 2.5 times, such as greater than or about 3 times, such as greater than or about 3.5 times, such as greater than or about 4 times, such as greater than or about 4.5 times, such as greater than or about 5 times, such as greater than or about 5.5 times, such as greater than or about 6 times, such as greater than or about 6.5 times, such as greater than or about 7 times, such as greater than or about 7.5 times, such as greater than or about 8 times, such as greater than or about 8.5 times, such as greater than or about 9 times, such as greater than or about 9.5 times, such as even greater than or about 10 times higher than a doping concentration of a section adjacent to or forming a contact with channel body 428, or gate/wordline 430.

While there are four additional sections illustrated in source/drain regions 404/410 (404b-404e, 410b-410e), it should be clear that the source/drain region 404 and/or 410 may have any number of sections so as one or more source/drain regions 404/410 exhibit the gradient discussed above. Furthermore, in embodiments, there may be no delineated sections, as instead, the doping concentration may gradually decrease moving from end 462/464 towards channel body 428 or increase moving from region 404f/410f adjacent to channel body 428 in case of double gate and/or single gate embodiments and wordline in case of gate-all-around embodiments, towards channel end 462/464 according to the distribution discussed above.

In embodiments, the gradient in the source/drain regions 404/410 may be formed by any one or more methods discussed above. However, in embodiments, the gradient may be imparted during formation of the one or more junctions 304/310. Namely, as discussed above, different levels of dopant in the low bandgap material may be included in the precursor materials during epitaxial growth of the layer(s). Thus, in embodiments, a higher percentage of dopant may be incorporated into the low bandgap material at or adjacent to the first junction layer 304 adjacent to substrate 302 and may be gradually decreased as the layer is formed (e.g. approaching formation of the channel material, or the opposite for second junction layer 310).

In embodiments, gas phase or plasma doping may be utilized to incorporate additional dopant into the desired sections, when starting with a precursor discussed herein, or may impart all of the dopant. For instance, the source/drain region may first be contacted with a lightly doped implant, gas phase, or plasma phase, adjacent to a channel body, followed by one or more higher energy implants or gas or plasma phases moving outward towards an end surface 462/464. Alternatively, a single or multiple doping operations may be utilized, but various anneal temperatures may be utilized. Furthermore, in embodiments, a combination of methods may be utilized, such as forming one or more lightly doped regions, followed by a high energy implant and/or varied anneal temperatures. Nonetheless, it should be clear that various methods may be utilized to form source/drain regions 404/410, to achieve a desired doping gradient.

However, in embodiments, it should be understood that the dopant may be achieved by forming a junction region as discussed herein, and then subjecting the region to thermal processing. In such embodiments, the dopant present in the junction region may migrate into the channel body based upon the processing temperature and time utilized.

As illustrated in the exemplary embodiment of FIG. 4C, the trench 414 may be filled with an insulative material 420, such as a dielectric material. In such a manner, the insulative material 420 may electrically isolate and support the metallized feature (discussed in greater detail below). Nonetheless, in embodiments, the insulative material 420 may be a dielectric material, such as an oxide containing material, a nitride containing material, or a combination thereof. In embodiments, insulative material 420 may include one or more of a silicon oxide, silicon oxycarbide, silicon oxynitride, silicon oxycarbonitride, combinations thereof, or other dielectric material as known in the art, formed utilizing any fill methods discussed above and as known in the art.

Turning to FIG. 4D, in the illustrated embodiment, one or more word line trenches 422 may be formed at operation 205. However, it should be understood that, in embodiments, a one or two step etch may be utilized that forms the word line trench through sacrificial material 406 to substrate 402. Regardless, in the illustrated embodiment, by utilizing a material with an etch selectivity to junction material 404, channel material 408, and junction material 410, the sacrificial material 406 may be retained during word line trench 422 formation. This may allow the space to be retained for a self-aligned bitline to be formed, if needed, or may be etched through as discussed above.

In embodiments, after trench 422 formation one or more additional components associated with a 4F² dynamic random-access memory (DRAM) device may be formed, as illustrated in FIG. 4E. For instance, a gate dielectric 424 may be formed generally around a perimeter of trench 422. Additionally or alternatively, if silicon is utilized as the channel material 408, the trench 422 may be subjected to in-situ steam generation to provide a silicon oxide as the gate dielectric 424 around the perimeter of trench 422. Nonetheless, in embodiments, the gate dielectric 424 may be a dielectric material, such as a silicon oxide, silicon oxycarbide, silicon oxynitride, silicon oxycarbonitride, combinations thereof, or other dielectric material as known in the art, formed utilizing any fill methods discussed above and as known in the art.

Moreover, as illustrated in FIG. 4E, in embodiments, a gate metal 426 may be formed within trench 422 along gate dielectric 424. The gate metal 426 may be a conductive material having a low resistivity, such as tungsten, molybdenum, titanium, zirconium, nickel, hafnium, cobalt, tin, tantalum, platinum, iron, niobium, palladium, a metal-containing species thereof, alloys thereof, or combinations thereof, deposited by any one or more methods as known in the art or as discussed above. Nonetheless, as shown, the gate metal 426 may be bottom punched to remove gate metal 426 from a bottom surface of the trench 422, separating adjacent gates 426.

After punching, an insulative material 427 may be filled in trench 422 between adjacent gates 426. Nonetheless, in embodiments, the insulative material may be a dielectric oxide, such as one or more of a silicon oxide, silicon oxycarbide, silicon oxynitride, silicon oxycarbonitride, combinations thereof, or other dielectric material as known in the art, formed utilizing any fill methods discussed above and as known in the art.

Furthermore, as shown, an insulative plug 429 may be formed between gate(s) 426 and upper surface 432 of channel 408. The plug 429 may be formed from any insulative material as known in the art, such as one or more dielectric materials including silicon nitride, a silicon oxynitride, silicon dioxide, or other similar materials. Although the description herein will regularly discuss silicon oxide or silicon nitride as a dielectric material and/or a spacer material, it is to be understood that any number of dielectric materials may be used in embodiments of the present technology, and the present technology should not be limited to any particular dielectric material in which features may be formed.

In embodiments, junction 410 may undergo a metallization process, such as silicidation to form a metallized interface over junction 410. For instance, a metal layer may be applied over junction 410 which is subsequently exposed to a silicidation process, forming metallized contact 436. In embodiments, the metal layer may be tungsten, molybdenum, titanium, zirconium, nickel, hafnium, cobalt, tin, tantalum, platinum, iron, niobium, palladium, a metal-containing species thereof, alloys thereof, or combinations thereof. Thus, the resulting interface may be a metallized layer of any one or more of the above metals and the channel material, such as silicon. In such an example only, the interface layer may be a titanium silicide, molybdenum silicide, hafnium silicide, or a combination thereof.

Nonetheless, one or more storage node contacts 434 or bit line contacts may be formed over the contacts 436. In embodiments, the metal may be tungsten, molybdenum, titanium, zirconium, nickel, hafnium, cobalt, tin, tantalum, platinum, iron, niobium, palladium, a metal-containing species thereof, alloys thereof, or combinations thereof. The storage node contact metal may be selected to be the same material or a different material than gate metal 426 discussed above. As illustrated, in embodiments, a storage node landing pad 438 may also be formed over storage node contact 434.

Regardless of how or when the source/drain regions 304 and 324 are formed, the semiconductor structure 300/400 may re-enter a normal process flow and undergo one or more further processing steps. For instance, the semiconductor structure may undergo contact redistribution, bonding pad formation, and/or copper contact formation. Nonetheless, semiconductor structure may exhibit a drastically reduced gate induced leakage current, off current leakage, and/or floating body effect.

It should be appreciated that the specific steps illustrated in the figures provide particular methods of forming 4F² DRAM arrays according to various embodiments. Other sequences of steps may also be performed according to alternative embodiments. For example, alternative embodiments may perform the steps outlined above in a different order. Moreover, the individual steps illustrated in the figures may include multiple sub-steps that may be performed in various sequences as appropriate to the individual step. Furthermore, additional steps may be added or removed depending on the particular applications. Many variations, modifications, and alternatives also fall within the scope of this disclosure.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A vertical cell dynamic random-access memory (DRAM) array, comprising:
one or more bit lines arranged in a first horizontal direction;
one or more word lines arranged in a second horizontal direction;
one or more channels extending in a vertical direction that is generally orthogonal to the first horizontal direction and the second horizontal direction such that the one or more bit lines intersect with a source/drain region of the one or more channels, and the one or more word lines intersect with a gate region of the one or more channels;
wherein the source/drain region comprises a low bandgap material, wherein the low bandgap material exhibits a bandgap less than a bandgap of a channel material.

2. The array of claim 1, wherein the source/drain region comprises silicon germanium.

3. The array of claim 2, wherein germanium is present in the silicon germanium in an amount of about 5 wt. % to about 60 wt. %.

4. The array of claim 1, wherein the source/drain region comprises a first section adjacent to the one or more channels and a second section opposite the first section, wherein the second section has a higher concentration of dopant than the first section.

5. The array of claim 4, wherein the second section has a dopant concentration that is at least about 2 times higher than a dopant concentration of the first section.

6. The array of claim 1, wherein the source/drain region comprises a drain region or a source region.

7. The array of claim 1, wherein the both the source and the drain comprises the low bandgap material.

8. The array of claim 1, wherein the gate region comprises a single gate, a double gate, or encircles the respective channel.

9. The array of claim 1, wherein the low bandgap material exhibits a bandgap that is less than or about 1 eV.

10. The array of claim 1, wherein the low bandgap material exhibits a bandgap that is at less than or about 10% of the bandgap of the channel material.

11. A method of forming a vertical cell dynamic random-access memory (DRAM) array, comprising:
forming a substrate, comprising:
a low bandgap material layer over a substrate material, and
one or more channel materials disposed over the low bandgap material layer,
etching the substrate to form one or more shallow trench isolations and a plurality of vertically extending channels having at least a first source/drain region;
wherein the first source/drain region is formed from the low bandgap material layer, and wherein the low bandgap material exhibits a bandgap less than a bandgap of the channel material.

12. The array according to claim 11, wherein the low bandgap material layer exhibits a doping gradient extending from a contact region to a channel region.

13. The array according to claim 12, wherein the low bandgap material layer is formed over the substrate material by epitaxial growth, and wherein a dopant concentration is increased or decreased during formation of the low bandgap material layer, forming the doping gradient.

14. The array according to claim 12, comprising further doping the low bandgap material layer, forming at least a portion of the doping gradient.

15. The array according to claim 11, wherein the low bandgap material layer comprises silicon germanium, and wherein germanium is present in the silicon germanium in an amount of about 5 wt. % to about 60 wt. %.

16. A method of forming a vertical cell dynamic random-access memory (DRAM) array, comprising:
etching a substrate to form one or more shallow trench isolations and a plurality of vertically extending channels;
contacting one or more of the plurality of vertically extending channels with a low bandgap dopant, forming a first source/drain region; and
forming a second source/drain region;
wherein the low bandgap material exhibits a bandgap less than a bandgap of a channel material.

17. The method of claim 16, wherein the first source/drain region is formed by contacting the one or more vertically extending channels with the dopant by plasma doping, gas phase doping, or a combination thereof.

18. The method of claim 17, further comprising annealing the one or more doped vertically extending channels.

19. The method of claim 17, wherein the plasma doping, gas phase doping, or combination thereof comprises a germanium dopant, and wherein germanium is present in the silicon germanium in an amount of about 5 wt. % to about 60 wt. % after contacting.

20. The method of claim 19, wherein at least a portion of one or more of the plurality of vertically extending channels comprises silicon germanium prior to the contacting.
